(19) United States
(12) Patent Application Publication
(10) Pub. No.: US 2010/0007017 A1
(43) Pub. Date: Jan. 14, 2010

(54) INTER-CONNECTING STRUCTURE FOR SEMICONDUCTOR PACKAGE AND METHOD FOR THE SAME

(75) Inventors: Shih-Chuan Wei, Yuanlin Township (TW); Dyi-Chung Hu, Chutung Township (TW); Yu-Shan Hu, Yangmei Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 12/172,431

(22) Filed: Jul. 14, 2008

(51) Int. Cl. H01L 23/488; H01L 21/58

(52) U.S. Cl. 257/737; 257/783; 438/118; 257/E23.023; 257/E21.505

(57) ABSTRACT

The present invention discloses an inter-connecting structure for a semiconductor package and a method for the same. The inter-connecting structure for the semiconductor package comprises a substrate formed to support a die thereon; core paste formed on the substrate and adjacent to the die; and a stiffener formed in an upper portion of the core paste, wherein the hardness of the stiffener is larger than the hardness of the core paste.

### FIELD OF THE INVENTION

The present invention relates to a semiconductor package, and more particularly to an inter-connecting structure for a semiconductor package and a method for the same.

### BACKGROUND OF THE INVENTION

The function of chip package includes power distribution, signal distribution, heat dissipation, protection and die encapsulation support as well-known in the art. As a semiconductor becomes more complicated, the traditional package technique, for example lead frame package, flex package or rigid package technique, can't meet the demand of producing smaller chip with high density elements thereon. In general, array packaging such as Ball Grid Array (BGA) packages provides a high density of interconnects relative to the surface area of the package. Typical BGA packages include a convoluted signal path, giving rise to high impedance and an inefficient thermal path which results in poor thermal dissipation performance. With increasing package density, the spreading of heat generated by the device is increasingly important. In order to meet packaging requirements for newer generations of electronic products, efforts have been expended to create reliable, cost-effective, small, and high-performance packages. Such requirements are, for example, reductions in electrical signal propagation delays, reductions in overall component area, and broader latitude in input/output (I/O) connection pad placement. In order to meet those requirements, a WLP (wafer level package) has been developed, wherein an array of I/O terminals is distributed over the active surface, rather than peripheral-leaded package. Such distribution of terminals may increase the number of I/O terminals and improve the electrical performance of the device. Further, the area occupied by the IC with interconnections when mounted on a printed circuit board is merely the size of the chip, rather than the size of a packaging lead-frame. Thus, the size of the WLP may be made very small. One such type may refer to chip-scale package (CSP).

Improvements in IC packages are driven by industry demands for improved thermal and electrical performance and reduced size and cost of manufacture. In the field of semiconductor devices, the device density is increased and the device dimension is reduced, continuously. The demand for the packaging or interconnecting techniques in such high density devices is also increased to fit the situation mentioned above. The formation of the solder bumps may be carried out by using a solder composite material. Flip-chip technology is well known in the art for electrically connecting a die to a mounting substrate such as a printed circuit board. The active surface of the die is subject to numerous electrical couplings that are usually brought to the edge of the chip. Electrical connections are deposited as terminals on the active surface of a flip-chip. The bumps include solders and/or plastics that make mechanical connections and electrical couplings to a substrate. The solder bumps after RDL have bump high around 50-100 um. The chip is inverted onto a mounting substrate with the bumps aligned to bonding pads on the mounting substrate, as shown in FIG. 1. If the bumps are solder bumps, the solder bumps on the flip-chip are soldered to the bonding pads on the substrate. Solder joints are relatively inexpensive, but exhibit increased electrical resistance as well as cracks and voids over time due to fatigue from thermo-mechanical stresses. Further, the solder is typically a tin-lead alloy and lead-based materials are becoming far less popular due to environmental concerns over disposing of toxic materials and leaching of toxic materials into ground water supplies.

Furthermore, because conventional package technologies have to divide a dice on a wafer into respective dies and then package the die respectively, these techniques are time-consuming for manufacturing process. Since the chip package technique is highly influenced by the development of integrated circuits, as the size of electronics has become demanding, so does the package technique. For the reasons mentioned above, today's trend of package techniques is toward ball grid array (BGA), flip chip (FC-BGA), chip scale package (CSP), and Wafer level package (WLP). “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

U.S. Pat. No. 6,271,469 discloses a package with RDL layer 124 as shown in FIG. 1. The microelectronic package includes a microelectronic die 102 having an active surface. An encapsulation material 112 is disposed adjacent the microelectronic die side(s), wherein the encapsulation material includes at least one surface substantially planar to the microelectronic die active surface. A first dielectric material layer 118 may be disposed on at least a portion of the microelectronic die active surface and the encapsulation material surface. At least one conductive trace 124 is then disposed on the first dielectric material layer 118. The conductive trace(s) 124 is in electrical contact with the microelectronic die active surface. A second dielectric layer 126 and a third dielectric layer 136 acting as solder mask layer are subsequently formed over the die. Via holes 132 are formed within the second dielectric layer 126 for coupling to the traces 124. The metal pads 134 acting as UBM function are connected to the via holes 132 and solders 138 are located on the pads. At least one conductive trace extends vertically adjacent the microelectronic die active surface and vertically adjacent the encapsulation material surface.

The traditional microelectronic package as mentioned above still suffers some problems. For example, when a stress is applied on the solders 138 vertically, the solders 138, the metal pads 134, the conductive traces 124 and the dielectric players 118 and 126 will be pressed downwards because the encapsulation material 112 is elastic, such that the conductive traces 124 will be deformed to generate a drop height and become easy to crack.

Therefore, the present invention provides a solution to the aforementioned problem to increase the ball shear strength of the microelectronic package and to prevent the conductive traces from being deformed by an external force.

### SUMMARY OF THE INVENTION

The present invention discloses an inter-connecting structure for a semiconductor package and a method for the same. In one aspect of the present invention, the inter-connecting structure for the semiconductor package includes a substrate formed to support a die thereon; core paste formed on the substrate and adjacent to the die; and a stiffener formed in an upper portion of the core paste, wherein the hardness of the stiffener is larger than the hardness of the core paste. The inter-connecting structure for the semiconductor package further includes a gap formed between the side wall of the stiffener and the side wall of the die. Furthermore, an upper surface of the stiffener is substantially in the same level with an upper surface of the die. The thickness of the stiffener is about 12.5-125 micrometers and the material of the stiffener includes polyimides (PI), copper clad laminate (CCL), or liquid crystal polymer (LCP).

In another aspect of the present invention, the inter-connecting structure for the semiconductor package includes a substrate formed to support a die thereon; core paste formed on the substrate and adjacent to the die; a stiffener formed in an upper portion of the core paste, wherein the hardness of the stiffener is larger than the hardness of the core paste; a redistribution layer (RDL) formed in a stacked built-up layer formed on the stiffener and the core paste; and an under bump metallurgy (UBM) formed through the redistribution layer to be attached onto the upper surface of the stiffener. The inter-connecting structure for the semiconductor package further includes a gap formed between the side wall of the stiffener and the side wall of the die. Furthermore, the under bump metallurgy (UBM) is partially attached onto the upper surface of the stiffener. An upper surface of the stiffener is substantially in the same level with an upper surface of the die. The material of the stiffener includes polyimides (PI), copper clad laminate (CCL) or liquid crystal polymer (LCP), and the thickness of the stiffener is about 12.5-125 micrometers.

In still another aspect of the present invention, a method for forming an inter-connecting structure for a semiconductor package includes providing an alignment tool with an alignment pattern; attaching a die with bonding pads thereon and stiffeners onto the alignment tool with a gap between the die and the stiffeners; filling core paste on the die and the stiffeners and into the gap therebetween; attaching a substrate onto the core paste; and curing the core paste and separating the alignment tool from the die and the stiffeners.

One advantage of the present invention is that the inter-connecting structure for the semiconductor package can minimize the drop heights of the redistribution layers (RDLs).

Another advantage of the present invention is that the inter-connecting structure for the semiconductor package can decrease the risk of fractures of the redistribution layers (RDLs).

Still another advantage of the present invention is that the inter-connecting structure for the semiconductor package can increase the ball shear strength of the semiconductor package.

Yet another advantage of the present invention is that the inter-connecting structure for the semiconductor package can prevent the solder balls and the under bump metallurgies (UBMs) from falling away from the dielectric layer and the stiffeners when a stress is applied on the semiconductor package.

These and other advantages will become apparent from the following description of preferred embodiments taken together with the accompanying drawings and the appended claims.

### BRIEF DESCRIPTION OF THE DRAWINGS

The present invention may be understood by some preferred embodiments and detailed descriptions in the specification and the attached drawings below. The identical reference numbers in the drawings refer to the same components in the present invention. However, it should be appreciated that all the preferred embodiments of the invention are only for illustrating but not for limiting the scope of the claims and wherein:

FIG. 1 is a diagram of a microelectronic package in accordance with a prior art;

FIG. 2 is a diagram of an inter-connecting structure for a semiconductor package in accordance with one embodiment of the present invention;

FIG. 3 illustrates experimental data of the ball shear strength of the semiconductor package in accordance with one embodiment of the present invention;

FIG. 4 is a diagram of an inter-connecting structure for a semiconductor package in accordance with another embodiment of the present invention;

FIG. 5 is a diagram of an inter-connecting structure for a semiconductor package in accordance with still another embodiment of the present invention; and

FIG. 6 is a process diagram of a method for forming an inter-connecting structure for a semiconductor package in accordance with yet another embodiment of the present invention.

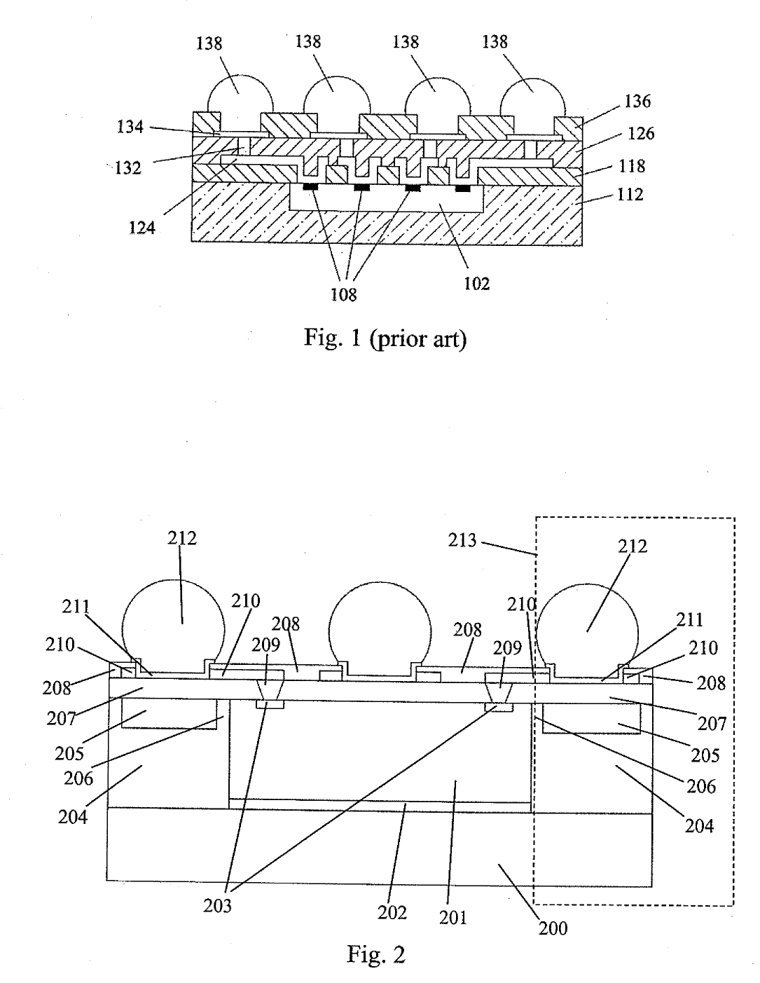

### DETAILED DESCRIPTION OF THE PREFERRED EMBODIMENT

The invention will now be described with the preferred embodiments and aspects and these descriptions interpret structure and procedures of the invention only for illustrating but not for limiting the claims of the invention. Therefore, except the preferred embodiments in the specification, the present invention may also be widely used in other embodiments.

The present invention discloses a semiconductor package with an inter-connecting structure and a method for the same. With reference to FIG. 2, in one embodiment of the present invention, a semiconductor package includes a substrate 200. In one embodiment, the substrate 200 could be made of a metal, alloy, silicon, glass, ceramic, plastics, printed circuit board (PCB) or polyimides (PI). In one embodiment, the alloy could be Alloy42 composed of 42% Ni and 58% Fe. The substrate 200 may have a thickness of about 40-200 micrometers and could be a single or multi-layer substrate. A die 201 is formed on the substrate 200 by an adhesive material 202, such that the adhesive material 202 fixes the die 201 onto the substrate 200. The adhesive material 202 may have elastic properties to absorb thermal stresses generated by CTE (Coefficient of Thermal Expansion) differences. The die 201 includes bonding pads 203 formed on the edges of the upper surface thereof. In one embodiment, the bonding pads 203 could be made of Al, Cu or other metal. Core paste 204 is formed adjacent to the die 201 and on the substrate 200 for protection. In one embodiment, the core paste 204 could be made of resin, compound, silicon rubber or epoxy.

Furthermore, stiffeners 205 are formed in the upper portion of the core paste 204 to render the upper surfaces of the stiffeners 205 to be substantially in the same level with the upper surface of the die 201, so as to increase ball shear strength of the semiconductor package because the stiffeners 205 are rigid and the hardness of the stiffeners 205 is larger than that of the core paste 204. As shown in FIG. 2, there is a gap 206 between the side walls of the stiffeners 205 and the side walls of the die 201. In one embodiment, the stiffeners 205 could be made of polyimides (PI), copper clad laminate (CCL) or liquid crystal polymer (LCP), and may have a thickness of 12.5-125 micrometers. A first dielectric layer 207 is formed on the stiffener 205 and the die 201, and then a second dielectric layer 208 is formed on the first dielectric layer 207. The first dielectric layer 207 includes openings 209 formed therein to expose the bonding pads 203. Redistribution layers (RDLs) 210 are formed within the openings 209 in the first dielectric layer 207 and within the second dielectric layer 208 to couple with the bonding pads 203 of the die 201. The redistribution layers (RDLs) 210 may be formed by an electroplating, plating or etching method and may be made of copper, nickel, or alloy. In the electroplating method, a copper (and/or nickel) electroplating operation continues until the copper (and/or nickel) layer reaches a desired thickness. The redistribution layers (RDLs) 210 extend out from the bonding pads 203 so as to form a fan-out type package. It should be noted that a plurality of partial portions of the second dielectric layer 208 on the redistribution layers (RDLs) 210 and a plurality of partial portions of the redistribution layers (RDLs) 210 are removed to form openings and expose a plurality of partial surfaces of the first dielectric layer 207. The plurality of partial portions of the second dielectric layer 208 on the redistribution layers (RDLs) 210 are aligned with the plurality of partial portions of the redistribution layers (RDLs) 210.

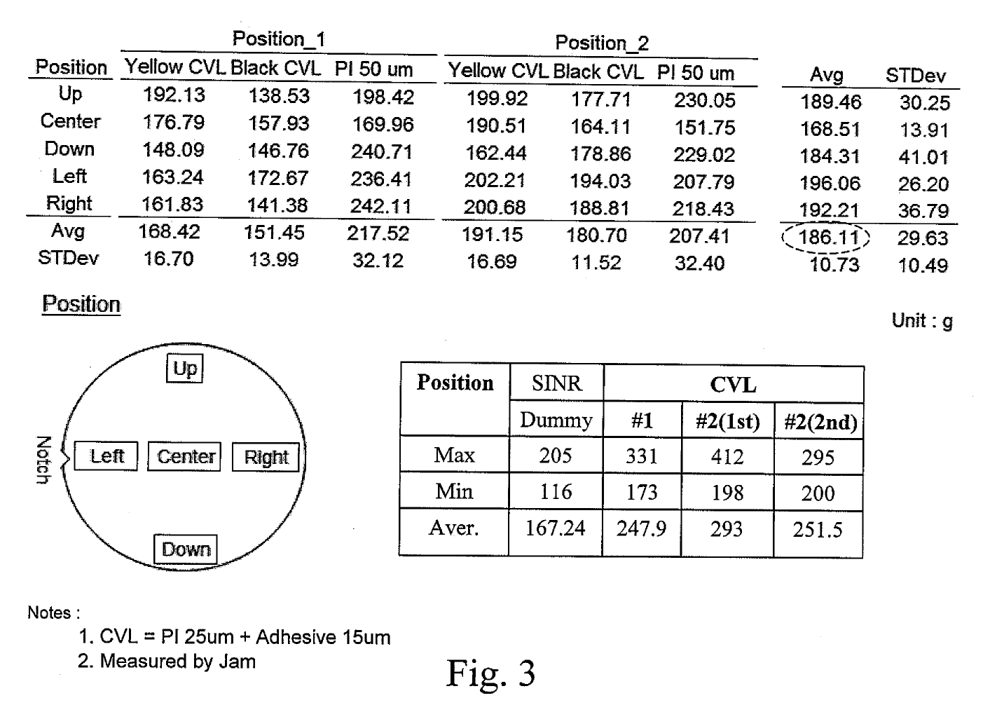

A plurality of under bump metallurgies (UBMs) 211 are formed on the plurality of partial exposed surfaces of the first dielectric layer 207 and on the side walls of the openings to receive and couple with a plurality of solder balls 212 as shown in FIG. 2. In one embodiment of the present invention, the inter-connecting structure 213 for the semiconductor package includes the substrate 200, the core paste 204, the stiffener 205, the stacked built-up layer (i.e. the first dielectric layer 207 and the second dielectric layer 208), the redistribution layer (RDL) 210, and the under bump metallurgy (UBM) 211, as shown in FIG. 2. When a stress is applied on the solder balls 212, the stiffeners 205 can prevent the solder balls 212, the under bump metallurgies (UBMs) 211, and the redistribution layers (RDLs) 210 near the solder balls 212 from being pressed downwards because of the hardness property of the stiffeners 205, thereby minimizing the drop heights of the redistribution layers (RDLs) 210 caused by the stress. Since the drop heights of the redistribution layers (RDLs) 210 are minimized, the risk of fractures of the redistribution layers (RDLs) 210 caused by the drop heights can be decreased, such that the ball shear strength of the semiconductor package is increased. As shown in FIG. 3, the ball shear strength of the semiconductor package in the present invention is about 186 g averagely. As known in the art, the ball shear strength of a traditional semiconductor package without the stiffener is about 120 g averagely. Therefore, the ball shear strength of the semiconductor package in the present invention increases 50% based on the ball shear strength of the traditional semiconductor package by utilizing the stiffeners 205.

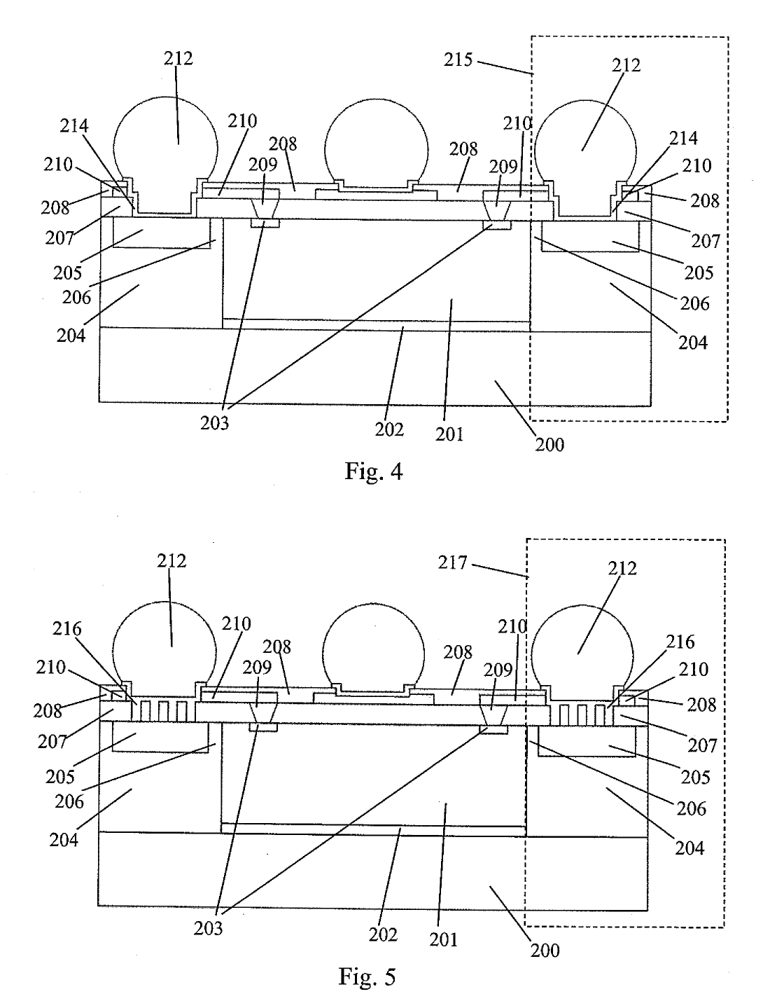

With reference to FIG. 4, in another embodiment, the present invention discloses an alternative semiconductor package. Most components in the alternative semiconductor package are similar to the aforementioned embodiment of FIG. 2 except the shape of the under bump metallurgies (UBMs) 214. The under bump metallurgies (UBMs) 214 in the alternative semiconductor package of FIG. 4 are disposed through the second dielectric layer 208 and the redistribution layers (RDLs) 210 and then enter the first dielectric layer 207, so as to be directly attached onto the upper surface of the stiffeners 205. In the another embodiment of the present invention, the inter-connecting structure 215 for the semiconductor package includes the substrate 200, the core paste 204, the stiffener 205, the stacked built-up layer (i.e. the first dielectric layer 207 and the second dielectric layer 208), the redistribution layer (RDL) 210, and the under bump metallurgy (UBM) 214, as shown in FIG. 4. Because the bonding strength between the under bump metallurgies (UBMs) 214 and the stiffeners 205 is stronger than the bonding strength between the under bump metallurgies (UBMs) 214 and the first dielectric layer 207, the under bump metallurgies (UBMs) 214 and the solder balls 212 attached thereon can be prevented from falling away from the dielectric layer 207 and the stiffeners 205 by attaching the under bump metallurgies (UBMs) 214 onto the stiffeners 205, such that the ball shear strength of the semiconductor package can be further increased.

With reference to FIG. 5, in still another embodiment, the present invention discloses another alternative semiconductor package. Most components in the current alternative semiconductor package are similar to the aforementioned embodiment of FIG. 4 except the shape of the under bump metallurgies (UBMs) 216. The under bump metallurgies (UBMs) 216 in the alternative semiconductor package of FIG. 5 are also disposed through the second dielectric layer 208 and the redistribution layers (RDLs) 210 and then partially enter the first dielectric layer 207, so as to be attached onto the partial upper surface of the stiffeners 205. In the still another embodiment of the present invention, the inter-connecting structure 217 for the semiconductor package includes the substrate 200, the core paste 204, the stiffener 205, the stacked built-up layer (i.e. the first dielectric layer 207 and the second dielectric layer 208), the redistribution layer (RDL) 210, and the under bump metallurgy (UBM) 216, as shown in FIG. 5. Because the bonding strength between the under bump metallurgies (UBMs) 216 and the stiffeners 205 is stronger than the bonding strength between the under bump metallurgies (UBMs) 216 and the first dielectric layer 207, the under bump metallurgies (UBMs) 216 and the solder balls 212 attached thereon can be prevented from falling away from the dielectric layer 207 and the stiffeners 205 by partially attaching the under bump metallurgies (UBMs) 216 onto the stiffeners 205, such that the ball shear strength of the semiconductor package can also be increased.

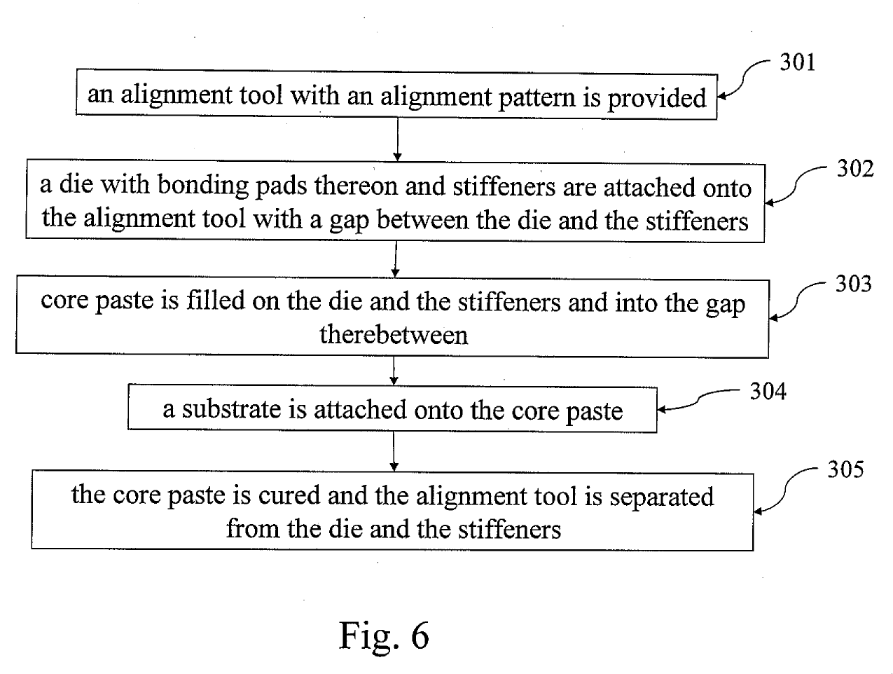

With reference to FIG. 6, in another embodiment, the present invention discloses a method for forming an inter-connecting structure for a semiconductor package. Firstly, in step 301, an alignment tool with an alignment pattern is provided. Then, in step 302, a die with bonding pads thereon and stiffeners are attached onto the alignment tool with a gap between the die and the stiffeners. Subsequently, in step 303, the core paste is filled on the die and the stiffeners and into the gap therebetween. Then, in step 304, a substrate is attached onto the core paste. Finally, in step 305, the core paste is cured and the alignment tool is separated from the die and the stiffeners.

Therefore, the present invention provides the inter-connecting structure which utilizes stiffeners to prevent the solder balls, the under bump metallurgies (UBMs), and the redistribution layers (RDLs) near the solder balls from being pressed downwards when a stress is applied on the semiconductor package, so as to minimize the drop heights of the redistribution layers (RDLs) 210 and the risk of fractures of the redistribution layers (RDLs) 210 and increase the ball shear strength of the semiconductor package. Moreover, the present invention provides the inter-connecting structure which can prevent the solder balls and the under bump metallurgies (UBMs) from falling away from the dielectric layer and the stiffeners when a stress is applied on the semiconductor package by attaching the under bump metallurgies (UBMs) onto the stiffeners directly or partially, so as to further increase the ball shear strength of the semiconductor package.

The foregoing description is a preferred embodiment of the present invention. It should be appreciated that this embodiment is described for purposes of illustration only, not for limiting, and that numerous alterations and modifications may be practiced by those skilled in the art without departing from the spirit and scope of the invention. It is intended that all such modifications and alterations are included insofar as they come within the scope of the invention as claimed or the equivalents thereof.

Having described the invention, the following is claimed:

1. An inter-connecting structure for a semiconductor package, comprising:
a substrate formed to support a die thereon;
core paste formed on said substrate and adjacent to said die; and
a stiffener formed in an upper portion of said core paste, wherein the hardness of said stiffener is larger than the hardness of said core paste.

2. The structure of claim 1, further comprising a gap formed between the side wall of said stiffener and the side wall of said die.

3. The structure of claim 1, wherein the material of said substrate comprises metal, alloy, silicon, glass, ceramic, plastics, printed circuit board (PCB) or polyimides (PI).

4. The structure of claim 1, wherein the material of said core paste comprises resin, compound, silicon rubber or epoxy.

5. The structure of claim 1, wherein an upper surface of said stiffener is substantially in the same level with an upper surface of said die.

6. The structure of claim 1, wherein the material of said stiffener comprises polyimides (PI), copper clad laminate (CCL), or liquid crystal polymer (LCP).

7. The structure of claim 1, wherein the thickness of said stiffener is about 12.5-125 micrometers.

8. An inter-connecting structure for a semiconductor package, comprising:
a substrate formed to support a die thereon;
core paste formed on said substrate and adjacent to said die;
a stiffener formed in an upper portion of said core paste, wherein the hardness of said stiffener is larger than the hardness of said core paste;
a redistribution layer (RDL) formed in a stacked built-up layer formed on said stiffener and said core paste; and
an under bump metallurgy (UBM) formed through said redistribution layer to be attached onto said upper surface of said stiffener.

9. The structure of claim 8, further comprising a gap formed between the side wall of said stiffener and the side wall of said die.

10. The structure of claim 8, further comprising a solder ball attached on said under bump metallurgy (UBM).

11. The structure of claim 8, wherein said under bump metallurgy (UBM) is partially attached onto said upper surface of said stiffener.

12. The structure of claim 8, wherein the material of said substrate comprises metal, alloy, silicon, glass, ceramic, plastics, printed circuit board (PCB) or polyimides (PI).

13. The structure of claim 8, wherein the material of said core paste comprises resin, compound, silicon rubber or epoxy.

14. The structure of claim 8, wherein an upper surface of said stiffener is substantially in the same level with an upper surface of said die.

15. The structure of claim 8, wherein the material of said stiffener comprises polyimides (PI), copper clad laminate (CCL), or liquid crystal polymer (LCP).

16. The structure of claim 8, wherein the thickness of said stiffener is about 12.5-125 micrometers.

17. The structure of claim 8, wherein the material of said redistribution layer (RDL) comprises copper, nickel, or alloy.

18. The structure of claim 8, wherein said redistribution layer (RDL) is formed by an electroplating, plating or etching method.

19. A method for forming an inter-connecting structure for a semiconductor package, comprising:
providing an alignment tool with an alignment pattern;
attaching a die with bonding pads thereon and stiffeners onto said alignment tool with a gap between said die and said stiffeners;
filling core paste on said die and said stiffeners and into said gap therebetween;
attaching a substrate onto said core paste; and
curing said core paste and separating said alignment tool from said die and said stiffeners.
